(19) United States
(12) Patent Application Publication
(10) Pub. No.: US 2026/0110740 A1
(43) Pub. Date: Apr. 23, 2026

(54) IMPEDANCE BALANCING FOR A MONITORING CIRCUIT OF A BATTERY OF A VEHICLE

(71) Applicant: GM GLOBAL TECHNOLOGY OPERATIONS LLC, DETROIT, MI (US)

(72) Inventor: Jihyun Kim, Rochester Hills, MI (US)

(21) Appl. No.: 18/919,891

(22) Filed: Oct. 18, 2024

(51) Int. Cl. G01R 31/367; G01R 31/00; G01R 31/382

(52) U.S. Cl. CPC G01R 31/367; G01R 31/007; G01R 31/382

(57) ABSTRACT

A method for impedance balancing for a monitoring circuit of a battery of a vehicle is provided. The method includes calculating a plurality of trace resistance values for a plurality of traces of the monitoring circuit, the monitoring circuit electrically connecting the battery to a cell monitoring unit, the battery comprising a plurality of cells. The method further includes determining a greatest trace resistance value of the plurality of trace resistance values. The method further includes calculating differences between the greatest trace resistance value and each of the plurality of trace resistance values. The method further includes identifying a subset of the plurality of traces having trace resistance values with a difference greater than a threshold resistance. The method further includes causing a resistor to be added to each of the subset of the plurality of traces having trace resistance values having the difference greater than the threshold resistance.

### BACKGROUND

The subject disclosure relates to vehicles, and in particular to impedance balancing for a monitoring circuit of a battery of a vehicle.

Many modern vehicles use batteries to store electrical power and distribute it to various components within the vehicles. Some vehicles use battery management systems, which are particularly useful for managing rechargeable batteries, such as in electric vehicles (EVs), hybrid electric vehicles (HEVs), plug-in hybrid electric vehicles (PHEVs), and energy storage systems. Battery management systems provide for monitoring the state of the battery, managing the charging and discharging processes, ensuring safety, and optimizing performance and longevity of the battery. It is desirable to provide impedance balancing for a monitoring circuit of a battery of a vehicle

### SUMMARY

In one embodiment, a computer-implemented method for impedance balancing for a monitoring circuit of a battery of a vehicle is provided. The method includes calculating a plurality of trace resistance values for a plurality of traces of the monitoring circuit, the monitoring circuit electrically connecting the battery to a cell monitoring unit, the battery comprising a plurality of cells. The method further includes determining a greatest trace resistance value of the plurality of trace resistance values. The method further includes calculating differences between the greatest trace resistance value and each of the plurality of trace resistance values. The method further includes identifying a subset of the plurality of traces having trace resistance values with a difference greater than a threshold resistance. The method further includes causing a resistor to be added to each of the subset of the plurality of traces having trace resistance values having the difference greater than the threshold resistance.

In addition to one or more of the features described herein, or as an alternative, further embodiments of the method may include that a resistance value for the resistor added to each of the subset of the plurality of traces having trace resistance values having the difference greater than the threshold resistance is based at least in part on the difference greater than the threshold resistance.

In addition to one or more of the features described herein, or as an alternative, further embodiments of the method may include that the resistor is selected from a group of resistors having pre-defined resistance values.

In addition to one or more of the features described herein, or as an alternative, further embodiments of the method may include that the resistor is selected from the group of resistors having pre-defined resistance values based at least in part on the difference greater than the threshold resistance.

In addition to one or more of the features described herein, or as an alternative, further embodiments of the method may include that the resistor is a surface mount device resistor.

In addition to one or more of the features described herein, or as an alternative, further embodiments of the method may include that the battery is a rechargeable battery.

In addition to one or more of the features described herein, or as an alternative, further embodiments of the method may include determining a minimum resistance variation for each of the plurality of traces, determining a maximum resistance variation for each of the plurality of traces, calculating an updated plurality of trace resistance values for the plurality of traces subsequent to adding the resistor to the monitoring circuit for each of the subset of the plurality of traces having trace resistance values having the difference greater than the threshold resistance, verifying that resistance values for the updated plurality of trace resistance values are within a range defined by the minimum resistance variation and the maximum resistance variation.

In addition to one or more of the features described herein, or as an alternative, further embodiments of the method may include that traces of the plurality of traces have substantially equal widths and substantially equal thicknesses.

In addition to one or more of the features described herein, or as an alternative, further embodiments of the method may include that the traces of the plurality of traces have varying lengths.

In addition to one or more of the features described herein, or as an alternative, further embodiments of the method may include that the plurality of cells of the battery are prismatic cells.

In addition to one or more of the features described herein, or as an alternative, further embodiments of the method may include that the plurality of cells of the battery are cylindrical cells.

In another embodiment, a processing system for performing impedance balancing of a monitoring circuit of a battery of a vehicle is provided. The processing system includes a memory having computer readable instructions and a processing device for executing the computer readable instructions, the computer readable instructions controlling the processing system to perform operations. The operations include calculating a plurality of trace resistance values for a plurality of traces of the monitoring circuit, the monitoring circuit electrically connecting the battery to a cell monitoring unit, the battery comprising a plurality of cells. The operations further include determining a greatest trace resistance value of the plurality of trace resistance values. The operations further include calculating differences between the greatest trace resistance value and each of the plurality of trace resistance values. The operations further include identifying a subset of the plurality of traces having trace resistance values with a difference greater than a threshold resistance. The operations further include identifying a resistor to be added to each of the subset of the plurality of traces having trace resistance values having the difference greater than the threshold resistance.

In addition to one or more of the features described herein, or as an alternative, further embodiments of the processing system may include that a resistance value for the resistor added to each of the subset of the plurality of traces having trace resistance values having the difference greater than the threshold resistance is based at least in part on the difference greater than the threshold resistance.

In addition to one or more of the features described herein, or as an alternative, further embodiments of the processing system may include that the resistor is selected from a group of resistors having pre-defined resistance values based at least in part on the difference greater than the threshold resistance.

In addition to one or more of the features described herein, or as an alternative, further embodiments of the processing system may include that the resistor is a surface mount device resistor.

In addition to one or more of the features described herein, or as an alternative, further embodiments of the processing system may include that the battery is a rechargeable battery.

In addition to one or more of the features described herein, or as an alternative, further embodiments of the processing system may include that the operations further include determining a minimum resistance variation for each of the plurality of traces, determining a maximum resistance variation for each of the plurality of traces, calculating an updated plurality of trace resistance values for the plurality of traces subsequent to adding the resistor to the monitoring circuit for each of the subset of the plurality of traces having trace resistance values having the difference greater than the threshold resistance, and verifying that the updated plurality of trace resistance values are within a range defined by the minimum resistance variation and the maximum resistance variation.

In addition to one or more of the features described herein, or as an alternative, further embodiments of the processing system may include that traces of the plurality of traces have substantially equal widths and substantially equal thicknesses.

In addition to one or more of the features described herein, or as an alternative, further embodiments of the processing system may include that traces of the plurality of traces have varying lengths.

In another embodiment a computer program product is provided. The computer program product includes a set of one or more computer-readable storage media and program instructions, collectively stored in the set of one or more storage media, for causing a processor set to perform computer operations for impedance balancing for a monitoring circuit of a battery of a vehicle. The computer operations include calculating a plurality of trace resistance values for a plurality of traces of the monitoring circuit, the monitoring circuit electrically connecting the battery to a cell monitoring unit, the battery comprising a plurality of cells. The operations further include determining a greatest trace resistance value of the plurality of trace resistance values. The operations further include calculating differences between the greatest trace resistance value and each of the plurality of trace resistance values. The operations further include identifying a subset of the plurality of traces having trace resistance values with a difference greater than a threshold resistance. The operations further include identifying a resistor to be added to each of the subset of the plurality of traces having trace resistance values having the difference greater than the threshold resistance. The operations further include determining a minimum resistance variation for each of the plurality of traces. The operations further include determining a maximum resistance variation for each of the plurality of traces. The operations further include calculating an updated plurality of trace resistance values for the plurality of traces subsequent to adding the resistor to the monitoring circuit for each of the subset of the plurality of traces having trace resistance values having the difference greater than the threshold resistance. The operations further include verifying that the updated plurality of trace resistance values are within a range defined by the minimum resistance variation and the maximum resistance variation.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 illustrates a vehicle with a circuit monitoring unit and a battery according to one or more embodiments;

FIG. 2 illustrates the circuit monitoring unit of FIG. 1 according to one or more embodiments;

FIGS. 3A, 3B, and 3C together illustrate the battery of FIG. 1 according to one or more embodiments;

FIG. 4 illustrates the battery and the monitoring circuit of FIG. 2 according to one or more embodiments;

FIG. 5 illustrates a flow diagram of a method for impedance balancing for a monitoring circuit of a battery of a vehicle according to one or more embodiments; and

FIG. 6 illustrates a block diagram of a processing system for impedance balancing for a monitoring circuit of a battery of a vehicle according to one or more embodiments.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

One or more embodiments described herein relates to impedance balancing for a monitoring circuit of a battery of a vehicle.

Many modern vehicles store electrical power in batteries and distribute the electrical power to various components. Some vehicles use battery management systems, which are particularly useful for managing batteries, such as in electric vehicles (EVs), hybrid electric vehicles (HEVs), plug-in hybrid electric vehicles (PHEVs), and energy storage systems. Battery management systems provide for monitoring the state of the battery, managing the charging and discharging processes, ensuring safety, and optimizing performance and longevity of the power storage unit. Battery management systems may utilize a cell monitoring unit to monitor cells of the battery using a monitoring circuit. The monitoring circuit connects the battery to the cell monitoring unit, which can sense properties of the battery, such as voltage and current, via the monitoring circuit. In some implementations, the monitoring circuit includes a trace for each cell of the battery so that the cell monitoring unit can monitor the cells of the battery individually.

In high voltage (e.g., substantially 400 volts to substantially 800 volts) power storage systems, such as in vehicles, imbalance in the monitoring circuit can occur due to the varying distances of traces between cells and the cell monitoring unit. This imbalance can lead to inaccuracies in voltage measurement and discrepancies in balancing currents.

Existing approaches attempt to address this issue by varying the trace width of the sensing circuits. For example, such an approach involves adjusting the width of the traces to match the impedance across different circuits. This approach often falls short due to physical constraints and design limitations, particularly in areas where traces converge near connector joints. The inability to achieve impedance matching can result in additional voltage drops and inaccuracies in cell voltage measurements, as well as imbalances in cell balancing currents. These shortcomings highlight the need for a more effective solution to ensure accurate and reliable monitoring of battery cell voltages.

One or more embodiments described herein overcome these and other shortcomings by providing impedance balancing for a monitoring circuit of a battery of a vehicle. One or more embodiments address impedance imbalance in monitoring circuits (e.g., cell voltage sensing circuits) by utilizing value-matched surface-mounted device (SMD) resistors on an intermediate inter-connect board (ICB) circuit. This approach involves designing traces with fixed thickness and fixed width, calculating the resistance values for each trace, and adding SMD resistors to at least one of the traces to equalize the impedance among the traces. By implementing this approach, the impedance discrepancies caused by varying trace lengths are mitigated, resulting in improved accuracy of cell voltage measurements and consistent cell balancing currents. This solution is particularly beneficial for high voltage battery designs with multiple stacked cells, ensuring reliable performance and extended battery life.

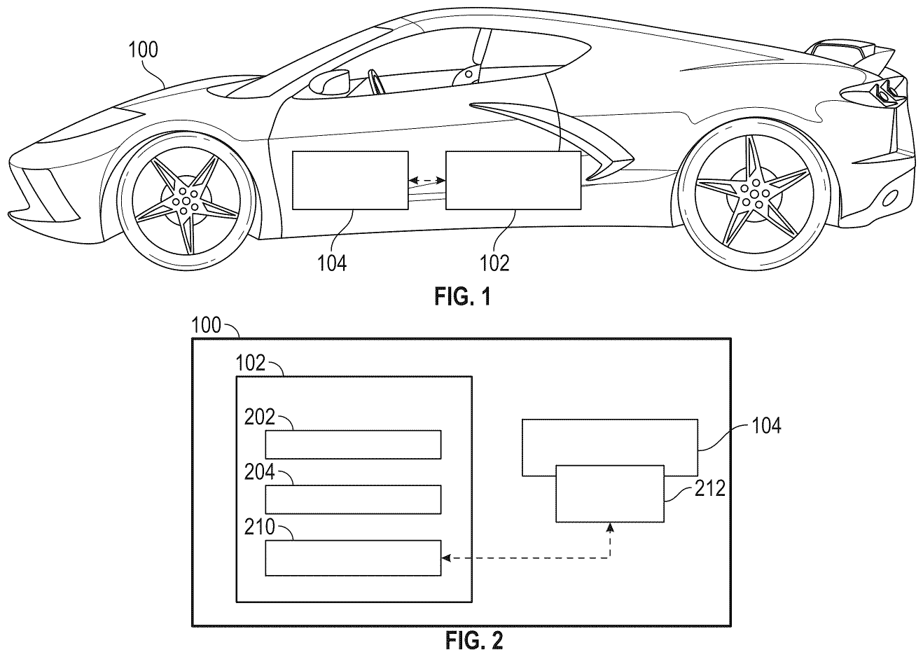

FIG. 1 shows a vehicle 100 with a cell monitoring unit 102 and a battery 104 according to one or more embodiments. The vehicle 100 can be a car, a truck, a van, a bus, a motorcycle, a boat, or any other type of automobile. According to an embodiment, the vehicle 100 is a hybrid electric vehicle, such as a plug-in hybrid electric vehicle (PHEV) partially or wholly powered by electrical power. According to another embodiment, the vehicle 100 is an electric vehicle powered by electrical power. The battery 104 is used to provide electrical power to components of the vehicle 100, such as an electric motor (not shown), electrical components (not shown), and/or the like, including combinations and/or multiples thereof. According to one or more embodiments, the vehicle 100 is an autonomous or semi-autonomous vehicle. An autonomous vehicle is a vehicle that has self-driving capabilities. A semi-autonomous vehicle is a vehicle that has certain autonomous features (e.g., self-parking, lane keeping, etc.) but lacks full autonomous control.

The cell monitoring unit 102 monitors and manages the performance of the battery 104. The battery 104 stores and provides electrical power. According to one or more embodiments, the battery 104 includes multiple cells. The battery 104 may be a high voltage (e.g., substantially 400 volts to substantially 800 volts) rechargeable battery.

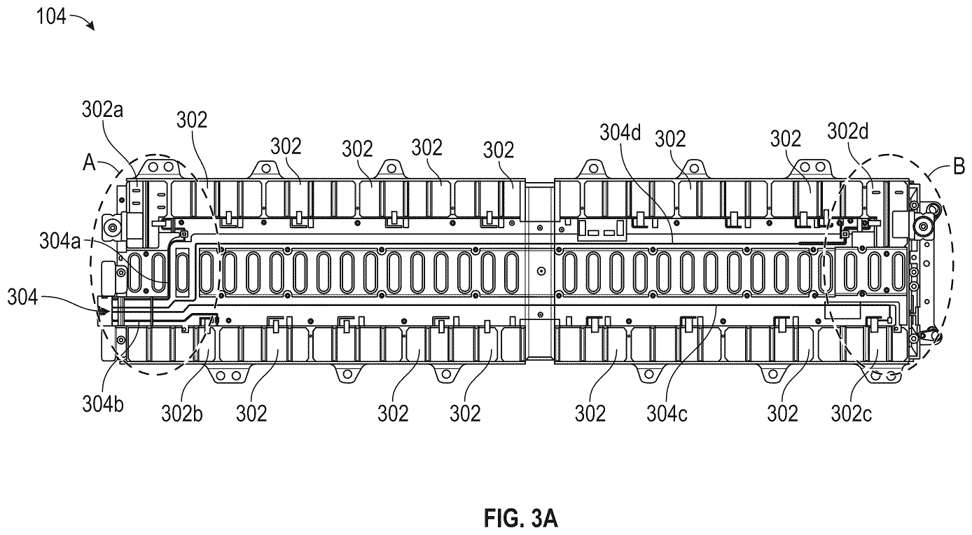

Further features of the cell monitoring unit 102 are now described with reference to FIGS. 2-5.

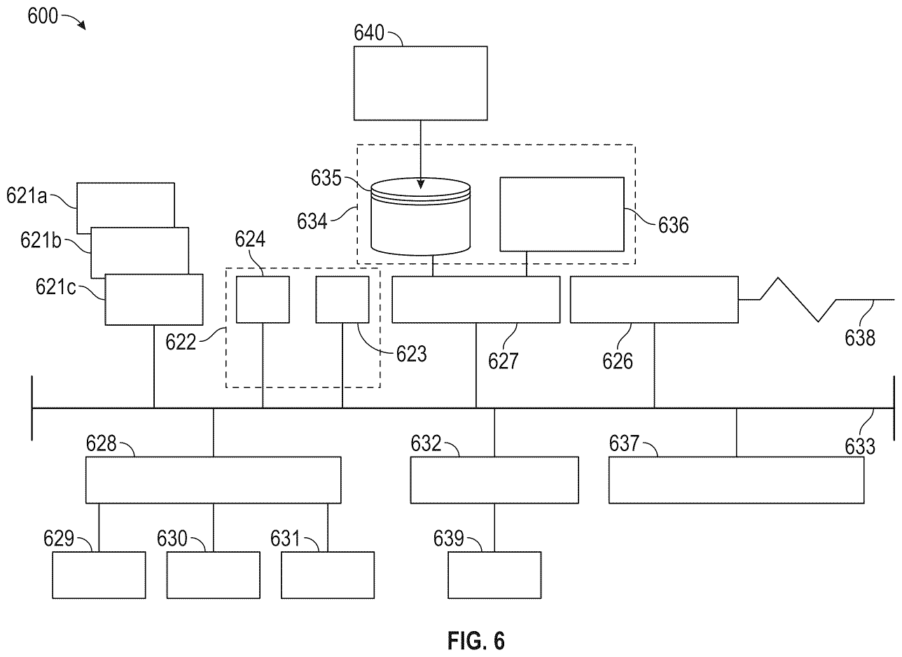

Particularly, FIG. 2 is a block diagram of the cell monitoring unit 102 of FIG. 1 according to one or more embodiments. According to one or more embodiments, the cell monitoring unit 102 includes a processing device 202, a memory 204, and a monitoring engine 210. It should be appreciated that the cell monitoring unit 102 can be any device suitable for monitoring and managing the battery 104. For example, the cell monitoring unit 102 can be a device implemented in or otherwise associated with the vehicle 100, such as an electronic control unit (also referred to as an electronic control module). As another example, the cell monitoring unit 102 can be a smartphone, tablet computer, laptop computer, desktop computer, wearable computing device, and/or the like, including combinations and/or multiples thereof. As yet another example, the cell monitoring unit 102 can be the processing system 600 of FIG. 6 and/or can include one or more components of the processing system 600 of FIG. 6.

The cell monitoring unit 102 monitors and manages the performance of the battery 104 (e.g., a high voltage rechargeable battery), including one or more cells of the battery 104. According to one or more embodiments, the cell monitoring unit 102 is responsible for ensuring accurate voltage sensing, effective cell balancing, and overall performance of the battery 104. The cell monitoring unit 102 receives information (e.g., signals) about the battery 104 from a monitoring circuit 212. According to one or more embodiments, the cell mounting unit 102 can be integrated into the battery 104. In other embodiments, the cell monitoring unit 102 can be separate from, and in communication with, the battery 104.

The cell monitoring unit 102 includes a processing device 202, which is any suitable processing circuitry for executing instructions and processing data. The processing device 202 can be a microcontroller, microprocessor, application-specific integrated circuit (ASIC), or any other type of processing unit capable of handling the computational demands of the cell monitoring unit 102. The processing device 202 is an example of one or more of the processing devices 621 of FIG. 6, as described in more detail herein.

The memory 204 within the cell monitoring unit 102 stores data and algorithms useful for operation of the cell monitoring unit 102. This may include real-time data processing, historical data analysis, and storage of firmware or software programs. The memory 204 is any suitable device for storing data and/or instructions. For example, the memory 204 can be a combination of volatile memory (e.g., random access memory) and non-volatile memory (e.g., read-only memory, flash memory). The memory 204 is an example of one or more of the system memory 622, the random access memory 623, and/or the read-only memory 624 of FIG. 6, as described in more detail herein.

The monitoring engine 210 is a specialized component within the cell monitoring unit 102 designed to monitor the battery 104. The monitoring engine 210 collects and processes data from the monitoring circuit 212, including voltage, current, and/or temperature measurements. According to one or more embodiments, the monitoring engine 210 ensures that the data is accurate and reliable, such as by validating the data, which enables the cell monitoring unit 102 to make informed decisions about the state of charge (SOC) and state of health (SOH) of the battery 104 and/or cells of the battery 104. According to one or more embodiments, the monitoring engine 210 performs impedance balancing for the monitoring circuit 212. Impedance balancing involves calculating the resistance values of the traces of the monitoring circuit 212 that connect the cells of the battery 104 to the cell monitoring unit 102, identifying discrepancies, and adding value-matched SMD resistors to substantially equalize the impedance. This ensures accurate voltage measurements and consistent cell balancing currents. Although the monitoring engine 210 is described as performing impedance balancing in this embodiment, it should be appreciated that the impedance balancing can be performed by other systems or devices. According to one or more embodiments, the processing system 600 of FIG. 6 performs the impedance balancing.

According to one or more embodiments, the cell monitoring unit 102 includes a communication interface (not shown) that enables the cell monitoring unit 102 to communicate with other systems of the vehicle 100, with external devices, or with a remote processing system. This interface can support various communication protocols, such as a controller area network (CAN) bus, local interconnect network (LIN) bus, or other automotive communication standards, enabling seamless integration with the electronic control units (ECUs) of the vehicle 100.

According to one or more embodiments, the cell monitoring unit 102 can be one component of a battery management system (BMS) (not shown), which can include battery protection features to protect the battery 104 and the vehicle 100. For example, the BMS can include over-voltage protection, under-voltage protection, over-current protection, and/or over-temperature protection. These safeguards help prevent damage to the battery cells and ensure the overall operational performance of the vehicle 100 and the battery 104.

According to one or more embodiments, the BMS manages the power flow to and from the battery cells of the battery 104, optimizing the charging and discharging processes. This helps to extend the lifespan of the battery 104 and improve the overall performance of the vehicle 100 and the battery 104.

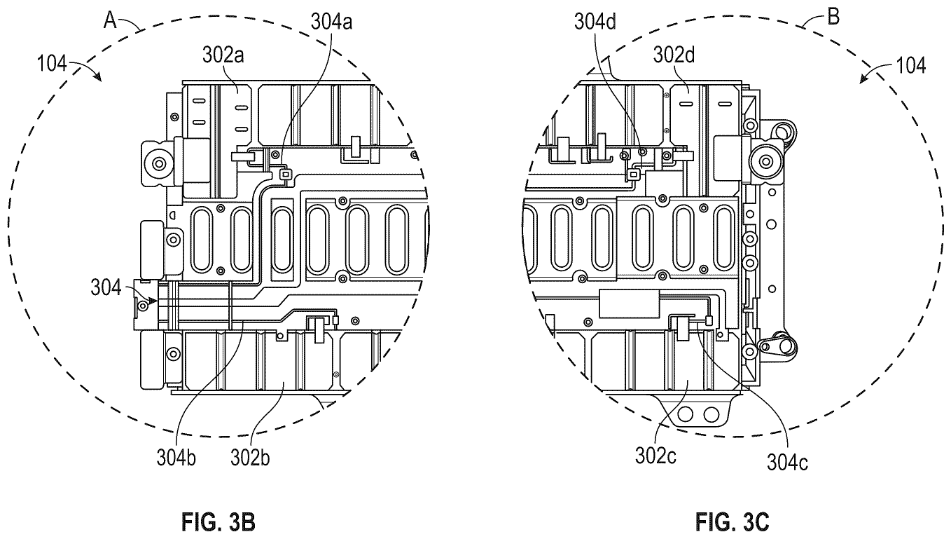

The various components, modules, engines, etc. (e.g., the monitoring engine 210) described regarding FIG. 2 can be implemented as instructions stored on a computer-readable storage medium, as hardware modules, as special-purpose hardware (e.g., application specific hardware, application specific integrated circuits (ASICs), application specific special processors (ASSPs), field programmable gate arrays (FPGAs), as embedded controllers, hardwired circuitry, etc.), or as some combination or combinations of these. According to aspects of the present disclosure, the engine(s) described herein (e.g., the monitoring engine 210) can be a combination of hardware and programming. The programming can be processor executable instructions stored on a tangible memory, and the hardware can include the processing device 202 for executing those instructions. Thus, a system memory (e.g., memory 204) and/or a computer-readable storage media can store program instructions that when executed by the processing device 202 implement the engine(s) described herein. Other engines can also be utilized to include other features and functionality described in other examples herein. Features and functionality of the monitoring engine 210 are now described in more detail with reference to FIGS. 3A-5.

Together, FIGS. 3A-3C illustrate the battery 104 according to one or more embodiments. The battery includes cells 302. The number and type of cells 302 may vary depending on the design of the battery 104. The cells 302 are connected to the monitoring circuit 212 via traces 304. In FIG. 3A, cell 302a is connected to trace 304a, cell 302b is connected to trace 304b, cell 302c is connected to trace 304c, and cell 302d is connected to trace 304d. FIGS. 3B and 3C illustrate details of the battery 104, including the cells 302a-302d.

As is evident in FIG. 3A, the traces 304a-304d vary in length and, consequently, vary in the amount of resistance inherent to the traces due to characteristics of the traces themselves (e.g., length, width, thickness, material type and characteristics, and/or the like, including combinations and/or multiples thereof). For example, consider a battery having fifty-six prismatic cells. In this example, a first group of cells that has a trace length of 28 millimeters (mm) has an inherent resistance of 0.03 ohms, and a last group of cells that has a trace length of 1882 mm has an inherent resistance of 1.90 ohms. In this example, the difference in inherent resistance is about 64 times higher resistance for the last cell group as compared to the first cell group.

With continued reference to FIG. 3A, the following table defines the trace lengths (in mm) for the traces 304a-304d and the associated inherent resistance values (in ohms):

| | Trace 304a | | Trace 304b | | Trace 304c | | Trace 304d | |
|---|---|---|---|---|---|---|---|---|
| Length | 255.62 | mm | 192.87 | mm | 1233.14 | mm | 1266.05 | mm |
| Inherent Resistance | 0.26 | ohms | 0.20 | ohms | 1.25 | ohms | 1.28 | ohms |

As is made evident by the table, traces having longer trace lengths tend to have higher inherent resistance values. It should be appreciated that the values in the table are illustrative examples and are not limiting.

To address the difference in inherent resistance caused by varying trace lengths, one or more embodiments described herein implement value matched SMD resistors on the traces (e.g., the traces 304a-304d) to resolve this impedance mismatching issue.

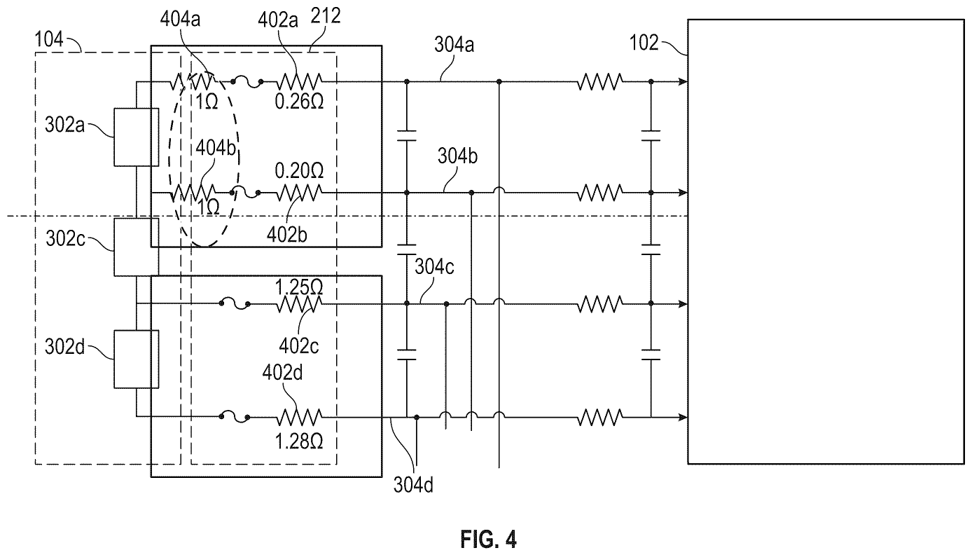

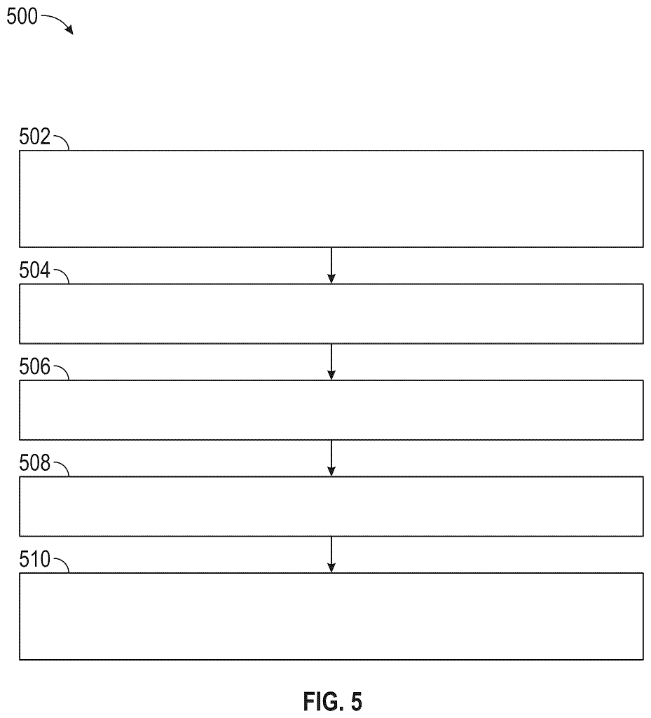

FIG. 4 illustrates the battery 104 and the monitoring circuit 212 of FIG. 2 according to one or more embodiments. To perform impedance matching on the monitoring circuit 212, the following process is performed according to one or more embodiments, which is described in more detail with reference to FIG. 5. Trace resistance values (e.g., the inherent resistance) are calculated for each of the traces, the greatest trace resistance value is determined, differences between the greatest resistance value and the trace resistance values for each trace are calculated, traces with significant discrepancies (e.g., greater than a threshold resistance) are identified, and resistors are added to traces to balance the impedance. These steps collectively ensure that the monitoring circuit 212 operates accurately and reliably, addressing the problem of impedance imbalance in high voltage rechargeable batteries.

In the example of FIG. 4, the inherent resistance for the traces are shown. For example, the trace 304a has an inherent resistance 402a of 0.26 ohms, the trace 304b has an inherent resistance 402b of 0.20 ohms, the trace 304c has an inherent resistance 402c of 1.25 ohms, and the trace 304d has an inherent resistance 402d of 1.28 ohms. The greatest trace resistance value is determined to be 1.28 ohms for the trace 304d (e.g., inherent resistance 402d), and this value used to calculate differences for each of the other traces. For example, the difference for the trace 304a is 1.02 ohms (1.28 ohms-0.26 ohms), the difference for the trace 304b is 1.08 ohms (1.28 ohms-0.20 ohms), and the difference for the trace 304c is 0.03 ohms (1.28 ohms-1.25 ohms). These differences are then compared to a threshold resistance, which may be a defined value or percent difference. For example, the threshold resistance may be 0.2 ohms (or another suitable value). In this example, the inherent resistances 402a, 402b are greater than the threshold resistance, and the inherent resistance 402c is not greater than the threshold resistance. An SMD resistor (e.g., resistors 404a and 404b) with a resistor value of 1.0 ohm can be added to each of the traces 304a, 304b to perform impedance matching. With the added resistor, the effective resistance value (namely the resistance value of the added resistor combined with the inherent resistance for the trace) for each of the traces 304a, 304b is within the threshold resistance relative to the inherent resistance of 402d of the trace 304d.

FIG. 5 illustrates a flow diagram of a method 500 for monitoring a plurality of cells of a battery of a vehicle (e.g., the vehicle 100) according to one or more embodiments. The method 500 can be implemented using any suitable system or device. For example, the method 500, and its steps, can be implemented using the cell monitoring unit 102 of FIGS. 1 and 2, by the processing system 600 of FIG. 6, and/or the like, including combinations and/or multiples thereof. The method 500 is now described with reference to FIGS. 1-4 but is not so limited.

At block 502, the method 500 includes calculating a plurality of trace resistance values for a plurality of traces (e.g., traces 304) of the monitoring circuit 212. A trace resistance value defines an amount of resistance (in ohms) inherent in the trace. That is, traces have an inherent amount of resistance depending on the dimensions (e.g., length, width, thickness), material type and characteristics, routing, etc., of the trace. For example, a longer trace has a higher trace resistance value as compared to a shorter trace, where other properties (e.g., width, thickness, material type and characteristics, etc.) are substantially the same. The monitoring circuit 212 electrically connects the battery 104 to the cell monitoring unit 102, and the battery 104 includes a plurality of cells (e.g., cells 302). According to one or more embodiments, the monitoring circuit 212 can be integrated into the battery 104 such that the battery 104 includes the monitoring circuit 212. This step ensures that the resistance values of the traces 304 are known, which is useful for subsequent impedance balancing.

At block 504, the method 500 includes determining a greatest trace resistance value among the plurality of trace resistance values. The greatest trace resistance value is the largest/highest value of resistance (in ohms) for the plurality of trace resistance values. Identifying the trace with the highest resistance value is useful for establishing a reference point for balancing the impedance of other traces.

At block 506, the method 500 includes calculating the differences between the greatest trace resistance value and each of the plurality of trace resistance values. That is, for each of the plurality of trace resistance values, the trace resistance value is subtracted from the greatest trace resistance value to determine a difference. This step quantifies the impedance discrepancies among the traces relative to the trace with the greatest trace resistance value, which is necessary for identifying which traces require adjustment.

At block 508, the method 500 includes identifying a subset of the plurality of traces having trace resistance values with a difference greater than a threshold resistance. For example, the threshold resistance may be set to a particular resistance value (e.g., 0.1 ohm), and any traces having a resistance value with a difference greater than 0.1 ohm are identified and included in the subset. This step filters out the traces that have significant impedance discrepancies, which are to be addressed to achieve balanced impedance, while bypassing traces with a nominal (e.g., less than the threshold resistance) difference.

At block 510, the method 500 includes causing a resistor (e.g., a SMD resistor) to be added to each of the subset of the plurality of traces having trace resistance values with a difference greater than the threshold resistance. That is, for each trace of the subset, a SMD resistor can be added to the trace to reduce the difference between the inherent resistance of the trace and the trace with the greatest trace resistance value. According to one or more embodiments, the added resistors are value-matched to equalize the impedance among the traces, ensuring accurate voltage measurements and consistent cell balancing currents. That is, the added resistors are selected based at least in part on the difference. According to one or more embodiments, the added resistors are selected from a group of resistors having pre-defined resistance values. This is useful where various standard resistors (e.g., resistors that are commercially available) are available, and the resistors to be added can be selected from the available standard resistors.

According to one or more embodiments, the method 500 can include performing a verification process to verify that trace resistance values, once the added resistor(s) are implemented, are satisfactory. The verification process ensures that the impedance balancing is effective and that the resistance values of the traces are within acceptable limits. The verification process is now described in more detail.

The verification process may begin by determining a minimum resistance variation for each of the plurality of traces. This step involves calculating the smallest difference in resistance values among the traces. The minimum resistance variation provides a baseline for understanding the range of resistance values present in the monitoring circuit 212.

Next, the verification process includes determining a maximum resistance variation for each of the plurality of traces. This step involves calculating the largest difference in resistance values among the traces. The maximum resistance variation helps identify the extent of impedance imbalance in the monitoring circuit 212.

Once the minimum and maximum resistance variations are determined, the verification process calculates an updated plurality of trace resistance values for the plurality of traces subsequent to adding the resistor to the monitoring circuit for each of the subset of the plurality of traces having trace resistance values having the difference greater than the threshold resistance. After adding the value-matched resistors to the traces with significant impedance discrepancies (e.g., greater than the threshold resistance), this step involves recalculating the resistance values for traces. This updated calculation ensures that the added resistors have effectively balanced the impedance.

The verification process concludes by verifying that the resistance values for the updated plurality of trace resistance values are within a range defined by the minimum resistance variation and the maximum resistance variation. This step involves checking that the recalculated resistance values fall within an acceptable range, defined by the minimum and maximum resistance variations. This verification step ensures that the impedance balancing has been successful and that the monitoring circuit is operating within the desired parameters.

Additional processes also may be included, and it should be understood that the processes depicted in FIG. 5 represent illustrations, and that other processes may be added, or existing processes may be removed, modified, or rearranged without departing from the scope of the present disclosure. It should also be understood that the processes depicted in FIG. 5 may be implemented as programmatic instructions stored on a non-transitory computer-readable storage medium that, when executed by a processor (e.g., the processing device 202 of FIG. 2, the processor(s) 621 of FIG. 6, and/or the like, including combinations and/or multiples thereof) of a computing system (e.g., the cell monitoring unit 102 of FIGS. 1 and 2, the processing system 600 of FIG. 6, and/or the like, including combinations and/or multiples thereof), cause the processor to perform the processes described herein.

One or more embodiments described herein offer several significant benefits over existing approaches for impedance matching in a monitoring circuit of a battery of a vehicle, particularly in terms of improving the monitoring circuit for a high voltage rechargeable battery. Such benefits may include one or more of the following:
Enhanced Accuracy in Voltage Sensing: By calculating the resistance values of each trace and adding value-matched resistors to balance the impedance, one or more embodiments ensures that the voltage drop across each trace is consistent. This leads to more accurate voltage measurements for each cell of the battery 104, which is useful for monitoring the SOC and the SOH of the cells of the battery 104. In contrast, existing approaches that vary trace widths often fail to achieve precise impedance matching, resulting in inaccurate voltage readings.
Consistent Cell Balancing Currents: Impedance balancing ensures that the balancing currents are consistent across cells of the battery 104. This is useful for effective cell balancing, which equalizes the charge across the cells to prevent overcharging and/or undercharging. Existing approaches that rely on varying trace widths can lead to discrepancies in balancing currents, causing some cells to degrade faster than others and reducing the overall lifespan of the battery 104.
Simplified Design and Manufacturing: One or more embodiments involves designing traces with fixed thickness and width, which simplifies the design and manufacturing process. Adding SMD resistors to balance the impedance is a straightforward and scalable solution. In contrast, existing approaches that vary trace widths can complicate the design and manufacturing process, especially in areas where traces converge near connector joints.
Improved Efficiency: By ensuring impedance balance, one or more embodiments minimizes energy losses due to heat generated by uneven resistance in the traces. This improves the overall energy efficiency of the battery 104. Existing approaches that fail to achieve precise impedance matching can result in higher energy losses, reducing the efficiency of the battery.
Enhanced Reliability: Impedance imbalance can lead to uneven heating and potential hotspots within the battery 104, increasing the risk of thermal runaway. One or more embodiments mitigates this risk by ensuring uniform impedance across traces, leading to more even temperature distribution. Existing approaches that do not achieve precise impedance matching can increase the likelihood of thermal issues, compromising the reliability of the battery pack.
Flexibility and Scalability: One or more embodiments can be adapted to various battery configurations, including different numbers of cells and cell types (e.g., prismatic or cylindrical cells). This flexibility makes one or more embodiments described herein suitable for a wide range of high voltage battery designs. Existing approaches that rely on varying trace widths may not be as easily adaptable to different battery configurations.

These and other benefits may be possible in various embodiments as described herein.

It is understood that one or more embodiments described herein is capable of being implemented in conjunction with any other type of computing environment now known or later developed. For example, FIG. 6 depicts a block diagram of a processing system 600 for implementing the techniques described herein. In accordance with one or more embodiments described herein, the processing system 600 is an example of a cloud computing node of a cloud computing environment. In examples, processing system 600 has one or more central processing units (referred to also as “processors” or “processing resources” or “processing devices”) 621a, 621b, 621c, etc. (collectively or generically referred to as processor(s) 621 and/or as processing device(s) 621). In aspects of the present disclosure, each processor 621 can include a reduced instruction set computer (RISC) microprocessor. Processors 621 are coupled to a system memory 622 and/or various other components via a system bus 633. The system memory 622 can include one or more temporary and/or persistent memory devices, such as a random access memory (RAM) 623, a read-only memory (ROM) 624, and/or the like, including combinations and/or multiples thereof. The system bus 633 may include a basic input/output system (BIOS), which controls certain basic functions of processing system 600.

Further depicted are an input/output (I/O) adapter 627 and a network adapter 626 coupled to system bus 633. I/O adapter 627 may be a small computer system interface (SCSI) adapter that communicates with a hard disk 635 and/or a storage device 636 or any other similar component. I/O adapter 627, hard disk 635, and storage device 636 are collectively referred to herein as mass storage 634. Operating system 640 for execution on processing system 600 may be stored in mass storage 634. The network adapter 626 interconnects system bus 633 with an outside network 638 enabling processing system 600 to communicate with other such systems.

A display (e.g., a display monitor) 639 is connected to system bus 633 by display adapter 632, which may include a graphics adapter to improve the performance of graphics intensive applications and a video controller. In one aspect of the present disclosure, adapters 626, 627, and/or 632 may be connected to one or more I/O buses that are connected to system bus 633 via an intermediate bus bridge (not shown). Suitable I/O buses for connecting peripheral devices such as hard disk controllers, network adapters, and graphics adapters typically include common protocols, such as the Peripheral Component Interconnect (PCI). Additional input/output devices are shown as connected to system bus 633 via user interface adapter 628 and display adapter 632. A keyboard 629, mouse 630, and speaker 631 may be interconnected to system bus 633 via user interface adapter 628, which may include, for example, a Super I/O chip integrating multiple device adapters into a single integrated circuit.

In some aspects of the present disclosure, processing system 600 includes a graphics processing unit (GPU) 637. Graphics processing unit 637 is a specialized electronic circuit designed to manipulate and alter memory to accelerate the creation of images in a frame buffer intended for output to a display. In general, graphics processing unit 637 is very efficient at manipulating computer graphics and image processing and has a highly parallel structure that makes it more effective than general-purpose CPUs for algorithms where processing of large blocks of data is done in parallel.

Thus, as configured herein, processing system 600 includes processing capability in the form of processors 621, storage capability including the system memory 622 and mass storage 634, input means such as keyboard 625 and mouse 630, and output capability including speaker 631 and display 639. In some aspects of the present disclosure, a portion of system memory 622 and mass storage 634 collectively store the operating system 640 to coordinate the functions of the various components shown in processing system 600.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A computer-implemented method for impedance balancing for a monitoring circuit of a battery of a vehicle, the method comprising:
calculating a plurality of trace resistance values for a plurality of traces of the monitoring circuit, the monitoring circuit electrically connecting the battery to a cell monitoring unit, the battery comprising a plurality of cells;
determining a greatest trace resistance value of the plurality of trace resistance values;
calculating differences between the greatest trace resistance value and each of the plurality of trace resistance values;
identifying a subset of the plurality of traces having trace resistance values with a difference greater than a threshold resistance; and
causing a resistor to be added to each of the subset of the plurality of traces having trace resistance values having the difference greater than the threshold resistance.

2. The computer-implemented method of claim 1, wherein a resistance value for the resistor added to each of the subset of the plurality of traces having trace resistance values having the difference greater than the threshold resistance is based at least in part on the difference greater than the threshold resistance.

3. The computer-implemented method of claim 1, wherein the resistor is selected from a group of resistors having pre-defined resistance values.

4. The computer-implemented method of claim 3, wherein the resistor is selected from the group of resistors having pre-defined resistance values based at least in part on the difference greater than the threshold resistance.

5. The computer-implemented method of claim 1, wherein the resistor is a surface mount device resistor.

6. The computer-implemented method of claim 1, wherein the battery is a rechargeable battery.

7. The computer-implemented method of claim 1, further comprising:
determining a minimum resistance variation for each of the plurality of traces;
determining a maximum resistance variation for each of the plurality of traces;
calculating an updated plurality of trace resistance values for the plurality of traces subsequent to adding the resistor to the monitoring circuit for each of the subset of the plurality of traces having trace resistance values having the difference greater than the threshold resistance; and
verifying that resistance values for the updated plurality of trace resistance values are within a range defined by the minimum resistance variation and the maximum resistance variation.

8. The computer-implemented method of claim 1, wherein traces of the plurality of traces have substantially equal widths and substantially equal thicknesses.

9. The computer-implemented method of claim 1, wherein traces of the plurality of traces have varying lengths.

10. The computer-implemented method of claim 1, wherein the plurality of cells of the battery are prismatic cells.

11. The computer-implemented method of claim 1, wherein the plurality of cells of the battery are cylindrical cells.

12. A processing system for performing impedance balancing of a monitoring circuit of a battery of a vehicle, the processing system comprising:
a memory comprising computer readable instructions; and
a processing device for executing the computer readable instructions, the computer readable instructions controlling the processing system to perform operations comprising:
calculating a plurality of trace resistance values for a plurality of traces of the monitoring circuit, the monitoring circuit electrically connecting the battery to a cell monitoring unit, the battery comprising a plurality of cells;
determining a greatest trace resistance value of the plurality of trace resistance values;
calculating differences between the greatest trace resistance value and each of the plurality of trace resistance values;
identifying a subset of the plurality of traces having trace resistance values with a difference greater than a threshold resistance; and
identifying a resistor to be added to each of the subset of the plurality of traces having trace resistance values having the difference greater than the threshold resistance.

13. The processing system of claim 12, wherein a resistance value for the resistor added to each of the subset of the plurality of traces having trace resistance values having the difference greater than the threshold resistance is based at least in part on the difference greater than the threshold resistance.

14. The processing system of claim 12, wherein the resistor is selected from a group of resistors having pre-defined resistance values based at least in part on the difference greater than the threshold resistance.

15. The processing system of claim 12, wherein the resistor is a surface mount device resistor.

16. The processing system of claim 12, wherein the battery is a rechargeable battery.

17. The processing system of claim 12, wherein the operations further comprise:
determining a minimum resistance variation for each of the plurality of traces;
determining a maximum resistance variation for each of the plurality of traces;
calculating an updated plurality of trace resistance values for the plurality of traces subsequent to adding the resistor to the monitoring circuit for each of the subset of the plurality of traces having trace resistance values having the difference greater than the threshold resistance; and
verifying that the updated plurality of trace resistance values are within a range defined by the minimum resistance variation and the maximum resistance variation.

18. The processing system of claim 12, wherein traces of the plurality of traces have substantially equal widths and substantially equal thicknesses.

19. The processing system of claim 12, wherein traces of the plurality of traces have varying lengths.

20. A computer program product comprising:
a set of one or more computer-readable storage media;
program instructions, collectively stored in the set of one or more storage media, for causing a processor set to perform computer operations for impedance balancing for a monitoring circuit of a battery of a vehicle, the computer operations comprising:
calculating a plurality of trace resistance values for a plurality of traces of the monitoring circuit, the monitoring circuit electrically connecting the battery to a cell monitoring unit, the battery comprising a plurality of cells;
determining a greatest trace resistance value of the plurality of trace resistance values;
calculating differences between the greatest trace resistance value and each of the plurality of trace resistance values;
identifying a subset of the plurality of traces having trace resistance values with a difference greater than a threshold resistance;
identifying a resistor to be added to each of the subset of the plurality of traces having trace resistance values having the difference greater than the threshold resistance;
determining a minimum resistance variation for each of the plurality of traces;
determining a maximum resistance variation for each of the plurality of traces;
calculating an updated plurality of trace resistance values for the plurality of traces subsequent to adding the resistor to the monitoring circuit for each of the subset of the plurality of traces having trace resistance values having the difference greater than the threshold resistance; and
verifying that the updated plurality of trace resistance values are within a range defined by the minimum resistance variation and the maximum resistance variation.
